(19) United States
(12) Patent Application Publication
(10) Pub. No.: US 2023/0320039 A1
(43) Pub. Date: Oct. 5, 2023

(54) INTEGRATED HEAT SPREADER

(71) Applicant: Honeywell International Inc., Charlotte, NC (US)

(72) Inventors: Prashant Hegde, Sriracha (TH); Nishanth Selvaraj, Sriracha (TH); Baskaran Selvan, Sriracha (TH)

(21) Appl. No.: 18/121,298

(22) Filed: Mar. 14, 2023

Related U.S. Application Data
(60) Provisional application No. 63/327,651, filed on Apr. 5, 2022.

(51) Int. Cl. H05K 7/20; B21D 53/04

(52) U.S. Cl. CPC H05K 7/20509; B21D 53/04

(57) ABSTRACT

A heat spreader including a top surface opposite a bottom surface, a cavity formed within and extending upwardly from the bottom surface, wherein the cavity includes an inner wall extending around the cavity and extending vertically downward from an inner cavity surface of the cavity. The heat spreader further includes an outer periphery extending vertically upward from the bottom surface of the heat spreader and extending around the cavity, and at least one step disposed within the cavity an having a surface that is positioned at a vertical height lower than a vertical height of the inner cavity surface of the cavity.

### CROSS-REFERENCE TO RELATED APPLICATION

This application claims priority to Provisional Application No. 63/327,651, filed Apr. 5, 2022, which is herein incorporated by reference in its entirety.

### TECHNICAL FIELD

The present disclosure relates generally to an integrated heat spreader and methods of forming an integrated heat spreader.

### BACKGROUND

Heat spreaders are often used in computer chip packages to draw heat from a chip, semiconductor die, and/or processor and transfer the heat to a heat sink to be dissipated. FIG. 1 illustrates a system established in the art and incorporates the use of heat spreaders. Specifically, a substrate 10 is shown positioned below a chip 12, also referred to as a die, that may be positioned adjacent and below a thermal interface material sheet 14. In some uses, the thermal interface material sheet 14 is composed of various types of polymers, such as silicone, for example. The chip 12 and thermal interface material sheet 14 may be arranged adjacent, and in some embodiments, within a recessed portion of, a heat spreader 20. The heat spreader 20 is arranged adjacent a second layer of the thermal interface material 14. Adjacent the second layer of the thermal interface material 14, the system may include a heat sink 18.

As a result of the above described configuration, during operation of the chip 12, heat generated by the chip 12 is discharged to the heat sink 18 via the heat spreader 20. The heat spreader 20 is able to disperse and spread the heat across the heat spreader 20, facilitating efficient heat transfer to the heat sink 18. In this way, the heat generated by the chip 12 does not cause localized damage to the components in the system. The heat that is dispersed by the heat spreader 20 may then be transferred to the heat sink 18 to be dissipated.

As previously described, in some instances, the heat spreader 20 may have a recess or cavity configured for receiving the chip 12. FIGS. 2A and 2B illustrate an additional embodiment of the heat spreader 20. As illustrated, the heat spreader 20 comprises a top side 22 and a bottom side 24, the bottom side 24 having a cavity 26 extending within the bottom side 24. In operation, the chip 12 (FIG. 1) may be arranged within the cavity 26. In these embodiments, it may be desired to have a recess and/or cavity of a shape and size that is optimized to engage with the chip 12 being incorporated into the system.

In manufacture, the heat spreaders 20 may be formed in large volumes by cutting a blank from the sheet or strip of bulk material and by using a combination of stamping processes to impart the desired shape and features to the blank to ultimately produce the desired heat spreader. When the heat spreader 20 includes the cavity 26, the cavity 26 may be formed from punching the material from the blank into a shape and geometry configured for receiving the processor or die in operation. During this process of punching the heat spreader 20 to form the desired shape, the punching force causes cold flow of the material from areas of high pressure into areas of lower pressure. As such, a stamping system can be designed with desired sizes and/or shapes to create the target shape of the cavity 26.

### SUMMARY

The present disclosure provides a heat spreader including a top surface opposite a bottom surface, a cavity formed within and extending upwardly from the bottom surface, wherein the cavity includes an inner wall extending around the cavity and extending vertically downward from an inner cavity surface of the cavity. The heat spreader further includes an outer periphery extending vertically upward from the bottom surface of the heat spreader and extending around the cavity, and at least one step disposed within the cavity and having a surface that is positioned at a vertical height lower than a vertical height of the inner cavity surface of the cavity.

In one form thereof, the present disclosure provides a heat spreader including a top surface opposite a bottom surface, a cavity extending from the bottom surface, wherein the cavity includes an inner wall extending around the cavity and extending vertically downward from an inner cavity surface of the cavity. The heat spreader additionally includes an outer periphery extending vertically upward from the bottom surface of the heat spreader and extending around the cavity, and four steps positioned within the cavity and arranged at four respective corners of the cavity, wherein each step extends from the outer periphery of the heat spreader to the inner cavity surface of the cavity, such that at least a portion of the cavity includes an inclined surface.

In another form thereof, the present disclosure provides a method of forming a heat spreader including stamping a central surface of a sheet of material with a die and a press of a stamping system to transfer material outward from a central surface forming a cavity and forming an outer periphery extending along the cavity, holding the material of the cavity constant such that a thickness of the cavity remains constant, and during the step of holding the material, stamping the outer periphery to transfer material inward from the central surface to define a plurality of steps within a plurality of corners of the cavity.

### BRIEF DESCRIPTION OF FIGURES

The above mentioned and other features of this invention, and the manner of attaining them, will become more apparent and the invention itself will be better understood by reference to the following description of embodiments of the invention taken in conjunction with the accompanying drawings, where:

FIG. 1 illustrates a schematic of an example use for a heat spreader;

FIG. 2A illustrates a heat spreader as is known generally in the art;

FIG. 2B illustrates a heat spreader as is known generally in the art;

FIG. 3 illustrates a schematic example press machine that may be used for manufacturing a heat spreader, in accordance with embodiments of the present disclosure;

FIG. 4A illustrates a heat spreader, in accordance with embodiments of the present disclosure;

FIG. 4B illustrates a cross-sectional view of the heat spreader of FIG. 4A, taken along the line 4B-4B, in accordance with embodiments of the present disclosure;

FIG. 4C illustrates an enlarged cross-sectional view of a portion of the heat spreader shown in FIG. 4B, illustrating a step in accordance with embodiments of the present disclosure;

FIG. 5A illustrates a heat spreader after a first step of manufacture, in accordance with embodiments of the present disclosure;

FIG. 5B illustrates a cross-sectional view of the heat spreader of FIG. 5A, taken along the line 5B-5B, in accordance with embodiments of the present disclosure;

FIG. 6A illustrates the heat spreader of FIG. 5A after a second step of manufacture, in accordance with embodiments of the present disclosure;

FIG. 6B illustrates a cross-sectional view of the heat spreader of FIG. 6A, taken along the line 6B-6B, in accordance with embodiments of the present disclosure;

FIG. 7A illustrates a bottom view of an additional embodiment of a heat spreader, in accordance with embodiments of the present disclosure;

FIG. 7B illustrates an enlarged bottom view of a portion of the heat spreader of FIG. 7A, showing a step in accordance with embodiments of the present disclosure;

FIG. 7C schematically illustrates a cross sectional view of the step shown in FIG. 7B, taken along line 7C-7C, in accordance with embodiments of the present disclosure;

FIG. 8A illustrates a bottom view of an additional embodiment of a heat spreader, in accordance with embodiments of the present disclosure;

FIG. 8B illustrates an enlarged bottom view of a portion of the heat spreader of FIG. 8A, showing a step in accordance with embodiments of the present disclosure;

FIG. 8C schematically illustrates a cross sectional view of the step shown in FIG. 8B, taken along line 8C-8C, in accordance with embodiments of the present disclosure;

FIG. 9A illustrates a bottom view of an additional embodiment of a heat spreader, in accordance with embodiments of the present disclosure;

FIG. 9B illustrates an enlarged bottom view of a portion of the heat spreader of FIG. 9A, showing a step in accordance with embodiments of the present disclosure; and

FIG. 9C schematically illustrates a cross sectional view of the step shown in FIG. 9B, taken along line 9C-9C, in accordance with embodiments of the present disclosure.

Corresponding reference characters indicate corresponding parts throughout the several views. Unless stated otherwise the drawings are drawn to scale and proportional.

### DETAILED DESCRIPTION

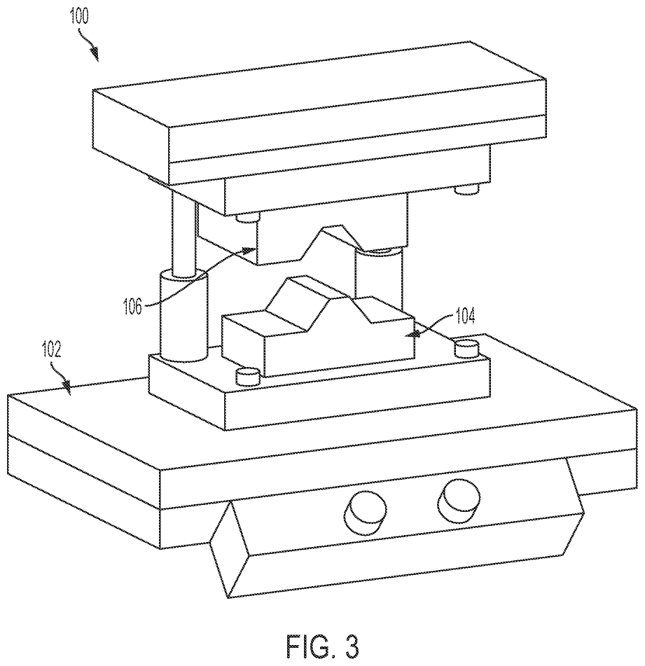

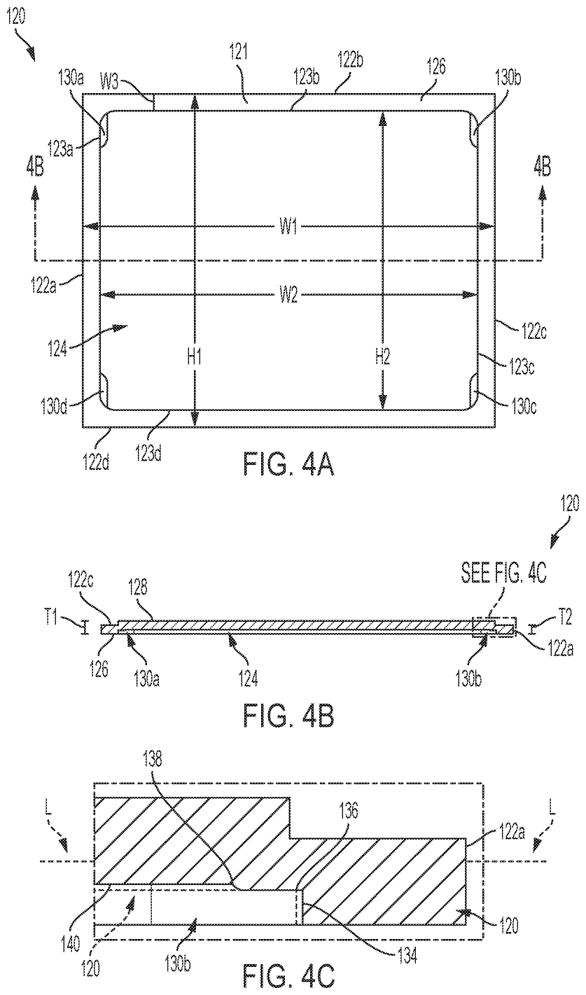

FIG. 3 schematically illustrates a stamping system 100 that may be used for forming a heat spreader, as will be described further with reference to FIGS. 4A-8B. Specifically, stamping system 100 includes a plate 102 for securing a die 104 in place. Die 104 and plate 102 are secured such that during the stamping process die 104 and plate 102 remain stationary. Stamping system 100 further includes a ram 106 that is configured for repeated motion up and down in a vertical direction. In operation, a sheet of material, for example a metal, may be placed onto die 104 and punch 106 may be actuated by a ram for downward motion onto the material. During this process, the punch 106 is forced downwardly onto the material within stamping system 100 to press the material to conform to the shape of die 104 and/or punch 106. For example, as illustrated, die 104 has a protrusion that extends upward while punch 106 has a corresponding V-shaped groove. As a result of this, once compressed the work piece between die 104 and punch 106 will have a projection matching the shape of the projection of die 104 and the groove of punch 106. While illustrated as having a projection, die 104 and/or punch 106 may have varying shapes and configurations. For example, die 104 and/or ram 106 may have a flat profile, domed profile, or otherwise irregularly shaped profile. Stamping system 100 may be used to form heat spreader 120, further described below, using a die 104 and punch 106 to perform one or more steps to cold-form a blank of material into the desired shape and configuration of heat spreader 120.

FIG. 4A illustrates a bottom view of an embodiment of a heat spreader 120 that may be formed from a stamping process, for example with stamping system 100 of FIG. 3, or a variation thereof. Heat spreader 120 defines a rectangular shape having a first side 122a, a second side 122b, a third side 122c and a fourth side 122d. A width W1 of heat spreader 120 is defined by distance between first side 122a and third side 122c, while heat spreader 120 defines a height H1 defined by a distance between second side 122b and fourth side 122d. In some embodiments, width W1 is approximately equal to height H1 such that heat spreader 120 is defined by a square shape, while in the illustrated embodiment, width W1 is greater than height H1.

Heat spreader 120 additionally comprises a central surface defining a cavity 124 which extends from a bottom surface 121 of heat spreader 120. Cavity 124 comprises a first side 123a, a second side 123b, a third side 123c, and a fourth side 123d. Each of sides 123a-d may be parallel to a respective side of sides 122a-d of heat spreader 120. Cavity 124 is defined by a width W2 and a height H2, wherein width W2 is less than width W1 and height H2 is less than height H1. Heat spreader 120 additionally defines an outer periphery 126 that extends along and between sides 122a-d of heat spreader 120 and sides 123a-d of cavity 124. In this embodiment, outer periphery 126 comprises a substantially constant width W3 around heat spreader 120, however in various embodiments, width W3 may vary depending on the positioning around the heat spreader 120. For example, width W3 may be smaller along one or more of sides 122a-d.

Further, with reference still to FIG. 4A, heat spreader 120 comprises a plurality of steps 130 positioned within the cavity 124 and adjacent to the periphery 126. More specifically, as illustrated in FIG. 4A, the plurality of steps 130 includes a first step 130a positioned generally at a corner defined between first side 123a and second side 123b, a second step 130b positioned generally at a corner defined between third side 123c and second side 123b, a third step 130c positioned generally at a corner defined between third side 123c and fourth side 123d, and a fourth step 130d positioned generally at a corner defined between first side 123a and fourth side 123d. As will be described further, the plurality of steps 130 are configured for providing an engagement surface between heat spreader 120 and an additional heat spreader that may be stacked onto heat spreader 120. In other words, the plurality of steps 130 function to ensure that a surface of cavity 124 does not contact a top surface of an adjacent heat spreader when stacked upon one another.

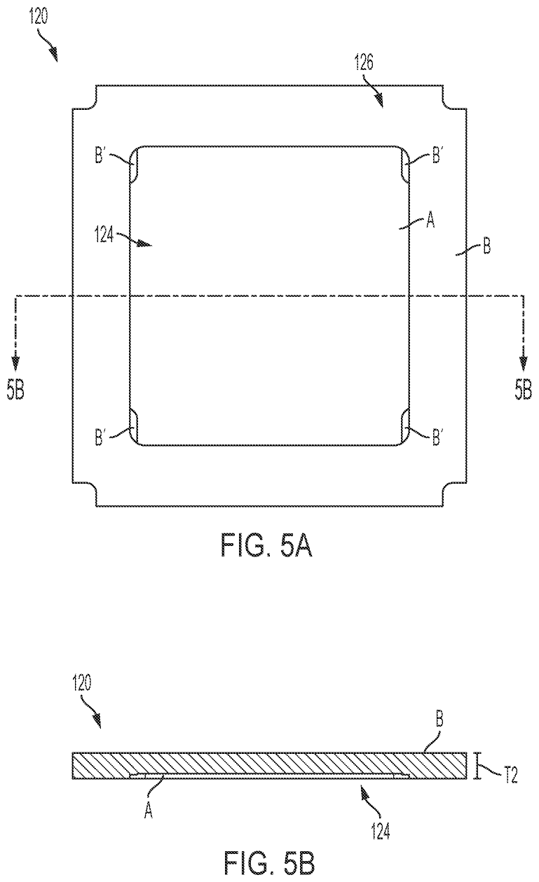

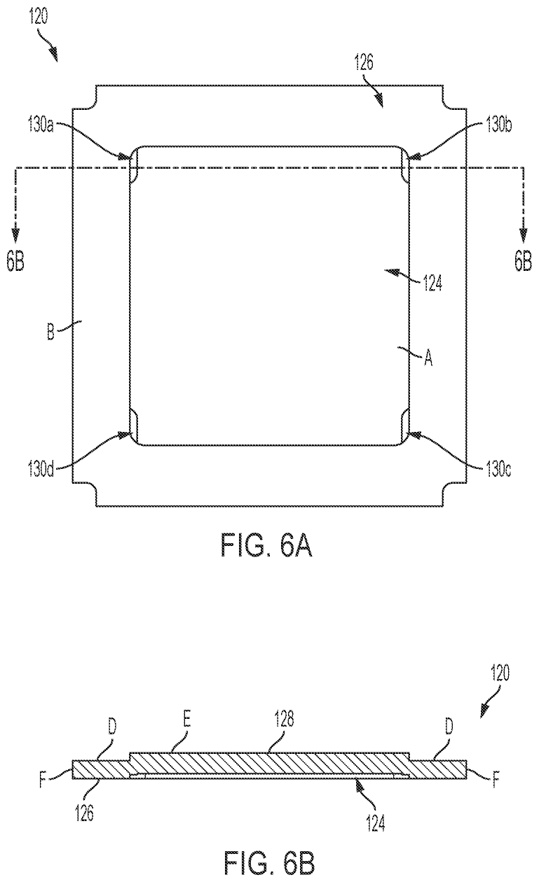

FIG. 4B illustrates the cross-sectional view of heat spreader 120 of FIG. 4A taken along line 4B-4B. Specifically, cavity 124 is illustrated opposite a top surface 128 of heat spreader 120. Heat spreader 120 defines a thickness T1 that may be greater than a thickness T2 of outer periphery 126. This varying thickness between outer periphery 126 and heat spreader 120 may be a result of the stamping process used for forming heat spreader 120, which will be described further below with reference to FIGS. 5A-6B.

The plurality of steps 130 will be described further with reference now to FIGS. 4B and 4C. With reference to the cross-sectional view of FIG. 4C, one of the plurality of steps 130 is shown, illustratively second step 130b. While the following description is made with respect to second step 130b, the description may apply to any one of the plurality of steps 130, which may all have the same shape, size and geometry as second step 130b described herein. As illustrated, cavity 124 has an inner wall 134 (FIG. 4C) that may extend around the entirety of cavity 124. As illustrated, inner wall 134 extends in a direction towards top surface 128 of heat spreader 120 and intersects with a raised surface 136 of second step 130b. As illustrated, raised surface 136 has a vertical height that is positioned lower than the vertical position of an inner cavity surface 140 of cavity 124. In other words, raised surface 136 extends vertically downward from inner cavity surface 140 of cavity 124. Second step 130b additionally includes a sloped surface 138 that intersects with inner cavity surface 140 of cavity 124. In these embodiments, inner wall 134 may extend all the way around cavity 124 such that within first step 130a, inner wall 134 intersects with a raised surface of the first step 130a, within third step 130c, inner wall 134 intersects with a raised surface of the third step 130c, and within fourth step 130d, inner wall 134 intersects with a raised surface of the fourth step 130d.

The raised surfaces 136 of the plurality of steps 130 allow for stacking of heat spreaders 120 without contact between top surface 128 of one of heat spreaders 120 and inner cavity surface 140 of cavity 124 of adjacent heat spreader 120. After manufacture, heat spreaders 120 may require transportation in bulk. During transportation, the heat spreaders 120 may be stacked upon one another in a tube. However, the cavity 124 of each heat spreader 120 may include precision surfaces which are ideally not contacted by any of the surfaces of the adjacent heat spreaders 120. As further described below, steps 130 allow for flexibility in the shape and/or geometry of the heat spreader 120 while reducing the potential for damage of sensitive surfaces within cavity 124 during handling and transport.

More specifically, when various of heat spreaders 120 are stacked, top surface 128 of a second heat spreader 120 can “nest” or be received in the cavity 124 of a first heat spreader 120, and when so received, the top surface 128 of the second heat spreader 120 contacts the raised surfaces of the plurality of steps 130 of the next adjacent heat spreader 120 without contacting the rest of the finished heat spreader surface 140 within cavity 124. In this way, after stacking of the plurality of heat spreaders 120, inner surface 140 of cavity 124 is protected from damage by contact with top surface 128 of second heat spreader 120 because steps 130 maintain a spacing between inner cavity surface 140 and the adjacent upper surface of the second heat spreader 120. For example, FIG. 4C schematically illustrates a second heat spreader 120 in phantom, illustrating the engagement between its top surface 128 and the raised surface 136 of second step 130b. The configuration of raised surface 136 in combination with outer periphery 126 of heat spreader 120 having a reduced thickness T2 as compared to thickness T1, allows for heat spreaders 120 to stack on top of one another without top surface 128 of one heat spreader 120 contacting inner cavity surface 140 of cavity 124 of adjacent heat spreader 120. Moreover, the only points of contact between two stacked heat spreaders 120 is between the steps 130 and the adjacent upper surface 128. In embodiments, inner cavity surface 140 of cavity 124 may have a surface coating, such as a gold plating, that is protected from damage or degradation due to contact between top surface 128 of adjacent heat spreader 120, thereby preserving maximum performance benefits from any such coating during use.

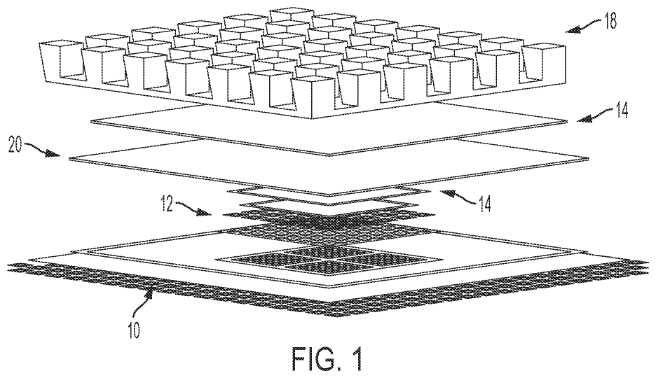

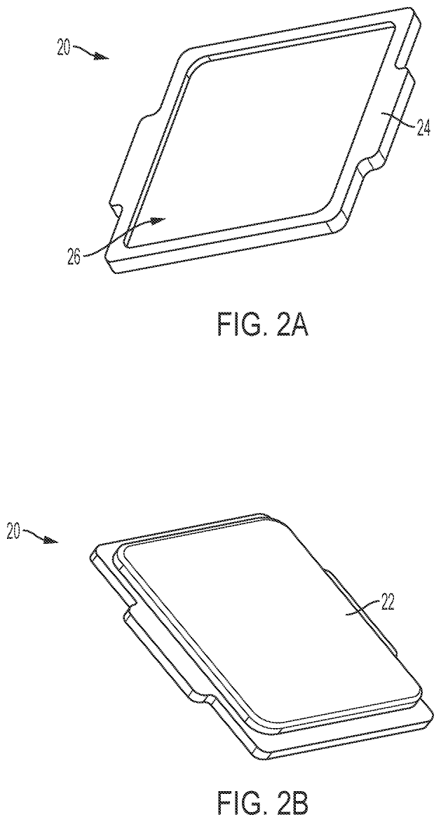

FIGS. 5A-6B illustrate various steps of manufacturing heat spreader 120 of FIG. 4A with the plurality of steps 130. Heat spreader 120 of FIGS. 5A-6B may be formed with stamping system 100, or a variation thereof, shown in FIG. 1. In some embodiments, the blank sheet of material is a sheet of copper. However, in other embodiments, other suitable materials may be incorporated.

With reference first to FIG. 5A, heat spreader 120 is illustrated in a partially-completed state after a blank sheet of material is inserted into the stamping system 100, and die 104 is stamped onto the surface A of heat spreader 120 to partially form cavity 124. Die 104 and punch 106 are shaped such that only surface A is pressed with stamping system 100, and as such, material is pressed outward and forms raised surfaces where the plurality of steps 130 (FIG. 4A) will reside. Specifically, the stamping process causes material to be pushed or flowed from surface A into four corners of the newly formed cavity 124. FIG. 5B illustrates a cross sectional view taken along line 5B-5B of FIG. 5A. As illustrated, the material of the original blank sheet of material has been pushed outward to form cavity 124 and create raised portions within the four corners, where the plurality of steps 130 will ultimately reside. After this first stamping process is complete, heat spreader 120 is defined by the thickness T1 and does not include outer periphery 126 having thickness T2 (FIG. 4B). This will be completed during the next step, as will be described further with respect to FIGS. 6A and 6B.

Specifically, the partially formed heat spreader 120 as shown in FIG. 5B, is inserted into stamping system 100 with a new arrangement for die 104 and punch 106, and the material undergoes a second stamping process, as will be described further with reference to FIGS. 6A-6B. During this step, stamping system 100 has been altered such that die 104 and punch 106 are configured to push the material down from surface B (FIG. 5B) while holding the material of surface A constant. In this way, the material from surface B is pushed and induced to flow into the corners of cavity 124 to form inner wall 134 of heat spreader 120. Further, during this step, stamping system 100 is configured to hold the material of surface F constant such that as the material is pushed from surface B into the corners of the cavity, outer periphery 126 is formed with desired thickness T2 (FIG. 4B).

During this step of pushing the material down from surface B, the material on surface A is secured in place to maintain the depth of cavity 124. In other words, material on surface A is secured such that the material is unable to flow into other areas of heat spreader 120. In parallel to squeezing the material of surface B and holding the material of surface A constant, the material on surface E is squeezed and/or compressed by die 104 (FIG. 3) and punch 106 (FIG. 3). The combination of holding the material of surface A while pushing the material of surface E causes the material from surface E to fill into surfaces B′ (FIG. 5A), which finishes the formation of the plurality of steps 130 and further defines inner wall 134 of cavity, as shown in FIG. 6A. Stated another way, steps 130 and inner wall 134 are “sharpened” by the material flow during the second stamping process.

Additionally, this process results in outer periphery 126 being formed with thickness T2 (FIG. 4B), which may be less than thickness T1 (FIG. 4B). The resulting shape of the now-finished heat spreader 120 is shown in the cross-sectional view of FIG. 6B and the first step 130a, which may be formed from the above described process, is shown in FIG. 4C for example.

In one embodiment, each of the steps 130 may be formed with a sloped surface 138, shown in FIG. 4C. Sloped surface 138 may act as a draft surface during the second step of manufacture. In other words, sloped surface 138 specifically aids in facilitating the material flow along the desired direction during the second step of the stamping process. Further, and as previously described, sloped surfaces 138 also act as the contact point for engaging with top surface 128 of an adjacent heat spreader 120. Engagement of top surface 128 of a first heat spreader 120 with sloped surface 138 of a second heat spreader 120a (FIG. 4C) reduces the area of contact required between the heat spreaders, which reduces the chances of damage or contamination to the heat spreaders during stacking as described above.

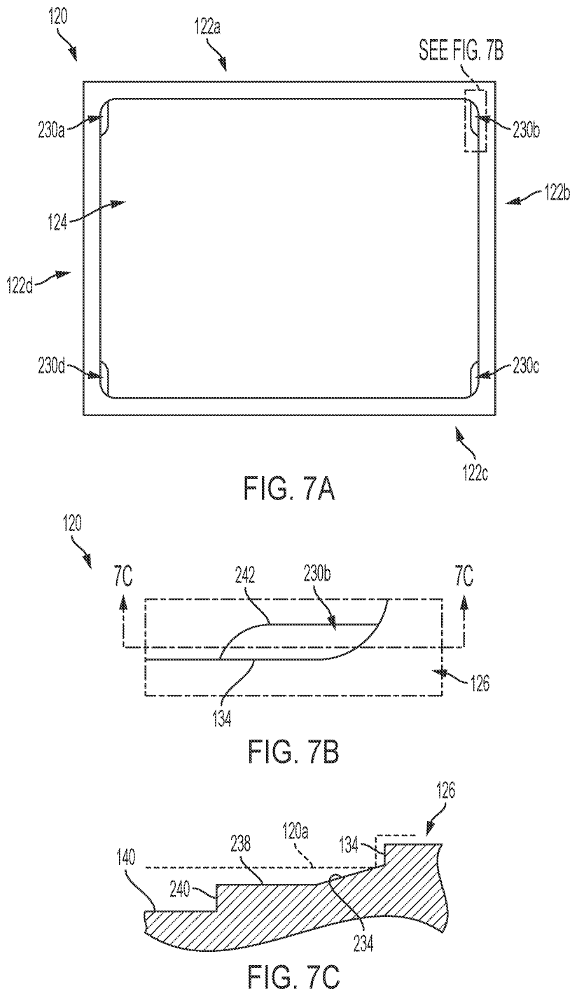

While the above method is described for forming heat spreader 120 as shown in FIGS. 4-4C, the process may be applied to form various configurations of heat spreader 120 and plurality of steps 130. For example, the shape of die 104 (FIG. 3) and/or punch 106 (FIG. 3) may be varied or altered in order to create a varying embodiment of the plurality of steps 130, as required or desired for a particular application. For example, variations of the plurality of steps incorporated with the heat spreader 120 will be described further herein with reference to FIGS. 7A-9C.

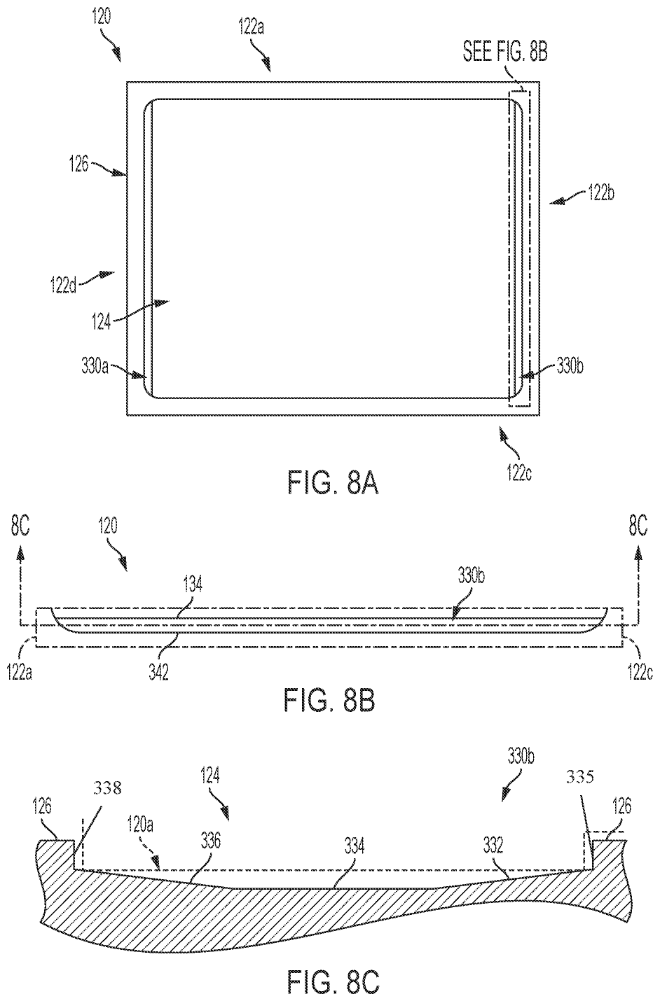

FIG. 7A illustrates the heat spreader 120 of FIG. 1 with a plurality of steps 230. Similar to the plurality of steps 130 shown in FIGS. 4A-4C, the plurality of steps 230 are positioned at each corner of heat spreader 120. More specifically, a first step 230a is positioned between first side 122a and fourth side 122d, a second step 230b is positioned between first side 122a and second side 122b, a third step 230c is positioned between second side 122b and third side 122c, and a fourth step 230d positioned between third side 122c and fourth side 122d. While illustrated as having four steps 230, any number of steps may be incorporated. For example, as will be described with reference to FIGS. 8A-8C, heat spreader 120 may include two steps. In other embodiments, heat spreader 120 may include four or more steps 230.

FIG. 7B illustrates a top and enlarged view of a first of the plurality of steps 230, more specifically, second step 230b. The following description is made with respect to second step 230b, however it may apply to any of the plurality of steps 230. As illustrated, second step 230b may have an irregular shape defined by a first curved surface 242 and a second curved surface, the second curved surface defined by the inner wall 134 of the cavity 124. FIG. 7C illustrates an exaggerated view of the cross sectional profile of second step 230b, the cross section taken along the line 7C-7C shown in FIG. 7B. As illustrated, second step 230b comprises an inclined portion 234 intersecting with inner wall 134 of heat spreader 120 and inner cavity surface 140 of cavity 124. Inclined portion 234 extends from outer periphery 126 of heat spreader 120, while a flat portion 238 extends from inclined portion 234. Inclined portion 234 may extend downward with an angle of approximately 2 degrees to 4 degrees relative to longitudinal axis L (FIG. 4B) of heat spreader 120. Flat portion 238 extends from inclined portion 234 to couple with a cliff portion 240 that connects to inner cavity surface 140 of cavity 124. Similar to the plurality of steps 130 described with reference to FIGS. 4A-4C, the profile of the plurality of steps 230 allows for reduced contact between inner cavity surface 140 of cavity 124 and top surface 128 of the adjacent heat spreader 120 when heat spreaders 120 are stacked upon one another. For example, second heat spreader 120a is shown in phantom as resting on inclined portion 234 of second step 230b, such that a very small area of contact approximating line or point contact is made between the top surface of the adjacent heat spreader 120a and the step 230. Second heat spreader 120a thus does not contact inner cavity surface 140 of cavity 124 and avoids damaging the surfaces of cavity 124. In other embodiments, second heat spreader 120a may engage flat portion 238 of second step 230b while still protecting and preserving the functional surfaces of cavity 124.

FIG. 8A illustrates an additional embodiment of heat spreader 120 having a plurality of steps 330. In the illustrative embodiment of FIG. 8A, the plurality of steps 330 includes a first step 330a and a second step 330b. In this illustrative embodiment, first step 330a and second step 330b extend from second side 122b and fourth side 122d. FIG. 8B illustrates an enlarged bottom view of one of the plurality of steps 330, illustratively second step 330b. As illustrated, the shape and/or configuration of second step 330b is defined by a first curved surface 342 and a second linear surface, the first curved surface defined by the inner wall 134.

FIG. 8C illustrates a schematic, cross sectional profile of second step 330b taken along the line 8C-8C in FIG. 8B with exaggerated representations of the surfaces for clarity. Specifically, a cross sectional view of second step 330b extending between first side wall 122a and third side wall 122c. As illustrated, second step 330b includes a first inclined portion 332 coupled with outer periphery 126 of heat spreader 120 through a cliff portion 335. Extending from first inclined portion 332 is a flat portion 334. Flat portion 334 may be at the same vertical height as inner cavity surface 140 of cavity 124, or may sit proud of the inner surface 140. In other words, flat portion 334 may be contiguous with inner cavity surface 140 of cavity 124, or may form a step adjacent to surface 140. Extending from flat portion 334 is a second inclined portion 336 that is coupled to outer periphery 126 through a cliff portion 338. Inclined portions 332, 336 may extend downward with an angle of approximately 2 degrees to approximately 4 degrees relative to longitudinal axis L (FIG. 4B) of heat spreader 120. While described with reference to second step 330b, first step 330a may be defined by the same cross sectional profile as second step 330b.

The incorporation of inclined portions 332, 336 in this configuration reduces the area of contact between inner cavity surface 140 of cavity 124 and the top surface of an adjacent heat spreader 120a. In other words, similar to as described with reference to the plurality of steps 230, when at least one heat spreader 120 is stacked onto another heat spreader 120a, the top surface of the heat spreader 120a rests with a small area of contact, approximating line or point contact, on the inclined portions 332, 336 of the plurality of steps 330. For example, FIG. 8C illustrates a portion of second heat spreader 120a positioned stacked onto heat spreader 120 such that second heat spreader 120a engages with inclined portions 332, 336 of second step 330b, and second heat spreader 120a is spaced from inner cavity surface 140.

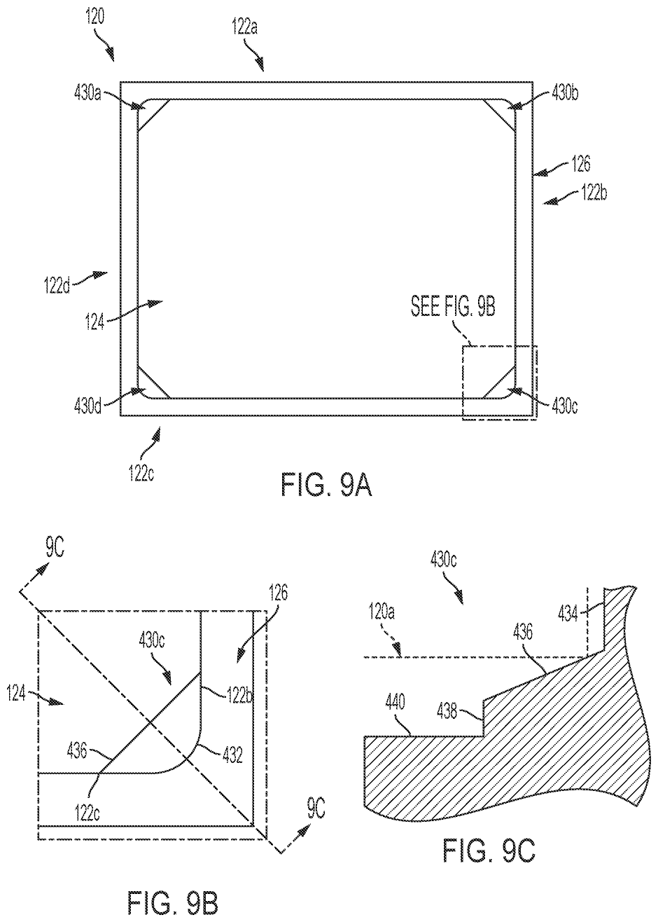

Further, FIGS. 9A-9C illustrate an additional embodiment of the heat spreader having a plurality of steps 430. In the illustrative embodiment, heat spreader 120 comprises a first step 430a, a second step 430b, a third step 430c and a fourth step 430d. FIG. 9B illustrates an enlarged, top view of one of the plurality of steps 430. Specifically, third step 430c is illustrated. While the following description is made with reference to third step 430c, the description may apply to any of the other steps 430a, 430b or 430d.

As illustrated in FIG. 9B, third step 430c may have a generally semi-oval and triangular shape. More specifically, the shape of third step 430c may be defined by a generally arcuate or curved surface 432 and a linear surface 436. As illustrated, linear surface 436 may extend from second side 122b to third side 122c of heat spreader 120. However, as previously noted, any of the other of the plurality of steps 430 may have the generally semi-oval and/or triangular shape and a respective curved surface and/or linear surface extending between various combinations of the first, second, third and fourth sides 122a-d of the heat spreader 120.

FIG. 9C schematically illustrates a cross sectional profile of third step 430c shown in FIG. 9B, with exaggerated representations of the surfaces for clarity. As illustrated, the generally cross-sectional profile of third step 430c includes an inclined portion 436 extending from inner wall 434 of the cavity. Inclined portion 436 may extend downward with an angle of approximately 2 degrees to approximately 4 degrees relative to longitudinal axis L (FIG. 4B) of heat spreader 120. Further, third step 430c is additionally defined by a cliff portion 438 extending vertically downward and coupled with a flat portion 440. As illustrated in phantom, second heat spreader 120a may engage with linear surface 436 such that contact between second heat spreader 120a and inner cavity surface 140 of cavity 124 is reduced.

### Aspects

Aspect 1 is a heat spreader including a top surface opposite a bottom surface, a cavity formed within and extending upwardly from the bottom surface, wherein the cavity includes an inner wall extending around the cavity and extending vertically downward from an inner cavity surface of the cavity. The heat spreader further includes an outer periphery extending vertically upward from the bottom surface of the heat spreader and extending around the cavity, and at least one step disposed within the cavity an having a surface that is positioned at a vertical height lower than a vertical height of the inner cavity surface of the cavity.

Aspect 2 is the heat spreader of Aspect 1, wherein the heat spreader is defined by a generally rectangular shape having a length, a width, and a depth.

Aspect 3 is the heat spreader of Aspect 2, wherein the cavity has a rectangular shape such that the cavity defines a length and a width.

Aspect 4 is the heat spreader of Aspect 3, wherein the outer periphery extends between the length of the heat spreader and the length of the cavity and between the width of the heat spreader and the width of the cavity.

Aspect 5 is the heat spreader of any of Aspects 1-4, wherein the cavity includes at least two steps extending parallel to and adjacent a first side and a third side of the cavity and extend the length of the cavity.

Aspect 6 is the heat spreader of any of Aspects 1-5, wherein the cavity includes at least two steps having a generally rectangular, semi-oval, or otherwise irregular shape.

Aspect 7 is the heat spreader of any of Aspects 1-6, wherein the cavity includes at least four steps positioned adjacent the inner wall of the cavity.

Aspect 8 is the heat spreader of any of Aspects 1-7, wherein the at least one step has an inclined portion extending from the inner wall of the cavity and a flat surface extending from the inclined surface to the bottom surface of the cavity.

Aspect 9 is the heat spreader of any of Aspects 1-8 wherein the at least one step includes a first inclined surface extending from the inner wall of the cavity, a second inclined surface extending from the cavity, and a flat surface extending between the first and second inclined surfaces.

Aspect 10 is the heat spreader of Aspect 9, wherein the flat surface is contiguous with the inner cavity surface of the cavity.

Aspect 11 is the heat spreader of any of Aspects 1-10, wherein the at least one step of the cavity includes a cliff portion extending vertically downward from the outer periphery of the heat spreader to an inclined portion, and wherein the inclined portion couples with a flat portion of the step.

Aspect 12 is the heat spreader of any of Aspects 1-11, wherein the heat spreader has an overall thickness defined by a thickness of the cavity and the bottom surface of the heat spreader, wherein the outer periphery has a thickness, and wherein the thickness of the outer periphery is less than the overall thickness of the cavity.

Aspect 13 is the heat spreader of any of Aspects 1-12, wherein the heat spreader is composed of copper.

Aspect 14 is a heat spreader including a top surface opposite a bottom surface, a cavity extending from the bottom surface, wherein the cavity includes an inner wall extending around the cavity and extending vertically downward from an inner cavity surface of the cavity. The heat spreader additionally includes an outer periphery extending vertically upward from the bottom surface of the heat spreader and extending around the cavity, and four steps positioned within the cavity and arranged at four respective corners of the cavity, wherein each step extends from the outer periphery of the heat spreader to the inner cavity surface of the cavity, such that at least a portion of the cavity includes an inclined surface.

Aspect 15 is the heat spreader of Aspect 14, wherein the inclined surface of each step is positioned at a vertical height that is lower than a vertical height of the bottom surface of the cavity.

Aspect 16 is the heat spreader of Aspect 14 or Aspect 15, wherein the heat spreader has a thickness that is greater than a thickness of the outer periphery.

Aspect 17 is a method of forming a heat spreader including stamping a central surface of a sheet of material with a die and a press of a stamping system to transfer material outward from a central surface forming a cavity and forming an outer periphery extending along the cavity, holding the material of the cavity constant such that a thickness of the cavity remains constant, and during the step of holding the material, stamping the outer periphery to transfer material inward from the central surface to define a plurality of steps within a plurality of corners of the cavity.

Aspect 18 is the method of Aspect 17, wherein the plurality of steps includes four steps and the plurality of corners includes four corners, and wherein each of the plurality of steps is arranged at one of the corners of the cavity.

Aspect 19 is the method of Aspect 17 or Aspect 18 wherein each of the steps has an inclined portion extending from the inner wall of the cavity and a flat surface extending from the inclined surface to the bottom surface of the cavity.

Aspect 20 is the method of any of Aspects 17-19, wherein each step includes a first inclined surface extending from the inner wall of the cavity, a second inclined surface extending from the cavity, and a flat surface extending between the first and second inclined surfaces.

While this invention has been described as having exemplary designs, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

1. A heat spreader, comprising:
a top surface opposite a bottom surface;
a cavity formed within and extending upwardly from the bottom surface, wherein the cavity comprises an inner wall extending around the cavity and extending vertically downward from an inner cavity surface of the cavity;
an outer periphery extending vertically upward from the bottom surface of the heat spreader and extending around cavity; and
at least one step disposed within the cavity and having a surface that is positioned at a vertical height lower than a vertical height of the inner cavity surface of the cavity.

2. The heat spreader of claim 1, wherein the heat spreader is defined by a generally rectangular shape having a length, a width, and a depth.

3. The heat spreader of claim 2, wherein the cavity has a rectangular shape such that the cavity defines a length and a width.

4. The heat spreader of claim 3, wherein the outer periphery extends between the length of the heat spreader and the length of the cavity and between the width of the heat spreader and the width of the cavity.

5. The heat spreader of claim 1, wherein the cavity includes at least two steps extending parallel to and adjacent a first side and a third side of the cavity and extend the length of the cavity.

6. The heat spreader of claim 1, wherein the cavity includes at least two steps having a generally rectangular, semi-oval, or otherwise irregular shape.

7. The heat spreader of claim 1, wherein the cavity includes at least four steps positioned adjacent the inner wall of the cavity.

8. The heat spreader of claim 1, wherein the at least one step has an inclined portion extending from the inner wall of the cavity and a flat surface extending from the inclined surface to the bottom surface of the cavity.

9. The heat spreader of claim 1, wherein the at least one step includes a first inclined surface extending from the inner wall of the cavity, a second inclined surface extending from the cavity, and a flat surface extending between the first and second inclined surfaces.

10. The heat spreader of claim 9, wherein the flat surface is contiguous with the inner cavity surface of the cavity.

11. The heat spreader of claim 1, wherein the at least one step of the cavity include a cliff portion extending vertically downward from the outer periphery of the heat spreader to an inclined portion, and wherein the inclined portion couples with a flat portion of the step.

12. The heat spreader of claim 1, wherein the heat spreader has an overall thickness defined by a thickness of the cavity and the bottom surface of the heat spreader, and wherein the outer periphery has a thickness, and wherein the thickness of the outer periphery is less than the overall thickness of the cavity.

13. The heat spreader of claim 1, wherein the heat spreader is composed of copper.

14. A heat spreader, comprising:
a top surface opposite a bottom surface;
a cavity extending from the bottom surface, wherein the cavity comprises an inner wall extending around the cavity and extending vertically downward from an inner cavity surface of the cavity;
an outer periphery extending vertically upward from the bottom surface of the heat spreader and extending around the cavity; and
four steps positioned within the cavity and arranged at four respective corners of the cavity, wherein each step extends from the outer periphery of the heat spreader to the inner cavity surface of the cavity, such that at least a portion of the cavity includes an inclined surface.

15. The heat spreader of claim 14, wherein the inclined surface of each step is positioned at a vertical height that is lower than a vertical height of the bottom surface of the cavity.

16. The heat spreader of claim 14, wherein the heat spreader has a thickness that is greater than a thickness of the outer periphery.

17. A method of forming a heat spreader, the method comprising:
stamping a central surface of a sheet of material with a die and a press of a stamping system to transfer material outward from a central surface forming a cavity and forming an outer periphery extending along the cavity;
holding the material of the cavity constant such that a thickness of the cavity remains constant; and
during the step of holding the material, stamping the outer periphery to transfer material inward from the central surface to define a plurality of steps within a plurality of corners of the cavity.

18. The method of claim 17, wherein the plurality of steps includes four steps and the plurality of corners includes four corners, and wherein each of the plurality of steps is arranged at one of the corners of the cavity.

19. The method of claim 17, wherein each of the steps has an inclined portion extending from the inner wall of the cavity and a flat surface extending from the inclined surface to the bottom surface of the cavity.

20. The method of claim 17, wherein each step includes a first inclined surface extending from the inner wall of the cavity, a second inclined surface extending from the cavity, and a flat surface extending between the first and second inclined surfaces.
